(19) United States
(12) Patent Application Publication
(10) Pub. No.: US 2010/0283053 A1
(43) Pub. Date: Nov. 11, 2010

(54) NONVOLATILE MEMORY ARRAY COMPRISING SILICON-BASED DIODES FABRICATED AT LOW TEMPERATURE

(75) Inventors: Mark H. Clark, Santa Clara, CA (US); S. Brad Herner, San Jose, CA (US)

Correspondence Address: DUGAN & DUGAN, PC, 245 Saw Mill River Road, Suite 309, Hawthorne, NY, 10532, US

(73) Assignee: SANDISK 3D LLC, Milpitas, CA (US)

(21) Appl. No.: 12/463,530

(22) Filed: May 11, 2009

(51) Int. Cl. H01L 29/861; H01L 21/20

(52) U.S. Cl. 257/49; 438/488; 257/530; 257/4; 257/E29.003; 257/E29.327; 257/E21.133

(57) ABSTRACT

In embodiments of the invention, a method of forming a monolithic three-dimensional memory array is provided, the method including forming a first memory level that includes a plurality of memory cells, each memory cell comprising a plurality of conductors comprising aluminum or copper, and forming a silicon diode in each memory cell, wherein the silicon diode is formed at temperatures compatible with the conductors. The silicon diode may be formed using a hot wire chemical vapor deposition technique, for example. Other aspects are also described.

### BACKGROUND

This invention relates to non-volatile memories, and more particularly to non-volatile memory arrays that include silicon-based diodes.

In conventional semiconductor devices, memory cells are fabricated in a monocrystalline silicon wafer substrate, with conductive wiring providing electrical connection to the memory cells. In general, these conductors can be formed after the array is formed, and thus need not be subjected to the temperatures required to form the memory cells themselves. Specifically, top metal conductors need not be subjected to the temperatures experienced during, for example, deposition and crystallization of silicon (in this discussion multi-grained silicon will be called polysilicon), which usually exceeds about 550° C. Thus, metals such as aluminum and copper that cannot tolerate high processing temperatures can successfully be used to form conductors in conventional two-dimensional semiconductor devices. Aluminum and copper are both very low-resistivity materials that are desirable for use in interconnects.

In monolithic three-dimensional memory arrays such as those described in Johnson et al., U.S. Pat. No. 6,034,882, “Vertically stacked field programmable nonvolatile memory and method of fabrication,” assigned to the assignee of the present invention and hereby incorporated by reference for all purposes, multiple memory levels are formed stacked atop one another above a monocrystalline silicon wafer substrate. Each memory level may include a steering element, such as a diode, a memory element, such as a dielectric rupture antifuse, and one or more conductors.

It would be advantageous to provide methods for fabricating a memory array that includes deposited semiconductor material and that is fabricated at low temperature, allowing the use of low-resistance conductors such as aluminum and copper before deposition of the semiconductor material.

### SUMMARY

In a first aspect of the invention, a method of forming a monolithic three-dimensional memory array is provided, the method including forming a first memory level that includes a plurality of memory cells, each memory cell including a plurality of conductors including aluminum or copper, and forming a silicon diode in each memory cell, wherein the silicon diode is formed at temperatures compatible with the conductors.

In a second aspect of the invention, a monolithic three-dimensional memory array is provided that is formed by forming a first memory level that includes a plurality of memory cells, each memory cell including a plurality of conductors including aluminum or copper, and forming a silicon diode in each memory cell, wherein the silicon diode is formed at temperatures compatible with the conductors.

In a third aspect of the invention, a monolithic three-dimensional memory array is provided that includes a first conductor including copper or aluminum, a polycrystalline silicon element coupled to the first conductor, and a second conductor coupled to the polycrystalline silicon element, the second conductor including copper or aluminum.

In a fourth aspect of the invention, a method of forming a memory cell is provided, the method including forming a conductor of copper or aluminum, and using a hot wire chemical vapor deposition technique to form a polycrystalline silicon element coupled to the conductor.

In a fifth aspect of the invention, a memory cell is provided that is formed by forming a conductor of copper or aluminum, and using a hot wire chemical vapor deposition technique to form a polycrystalline silicon element coupled to the conductor.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an exemplary memory cell;

FIG. 2A is a simplified perspective view of a portion of a first exemplary memory level formed from a plurality of the memory cells of FIG. 1;

FIG. 2B is a simplified perspective view of a portion of a first exemplary three-dimensional memory array in accordance with this invention;

FIG. 2C is a simplified perspective view of a portion of a second exemplary three-dimensional memory array in accordance with this invention;

FIG. 3 is a diagram of an exemplary memory cell in accordance with this invention;

FIGS. 4A-4C illustrate cross-sectional views of a portion of a substrate during a first exemplary fabrication of a single memory level in accordance with this invention; and

FIGS. 5A-5D illustrate cross-sectional views of a portion of a substrate during a second exemplary fabrication of a single memory level in accordance with this invention.

### DETAILED DESCRIPTION

In monolithic three dimensional memory arrays, multiple memory devices are formed stacked atop one another above a monocrystalline silicon wafer substrate. Each memory level may include a steering element, such as a diode, a memory element, such as a dielectric rupture antifuse, and one or more conductors. Conductors formed as part of a first memory level must be able to tolerate the processing temperatures required to form every element of the memory cells in the next layer, and in all subsequently formed memory layers. If the memory cell includes deposited amorphous silicon which must be crystallized, then, using conventional deposition and crystallization techniques, conductors must be able to tolerate temperatures exceeding, for example, 550° C. Aluminum wiring tends to soften and extrude at temperatures above about 475° C., and copper has even lower thermal tolerance. Thus, in fabricating monolithic three dimensional memory arrays, materials that can survive higher processing temperatures have been preferred for use as interconnects.

However, as memory arrays are scaled to smaller dimensions, the cross-sectional area of conductors shrinks, increasing their resistance. There is a need, therefore, for a robust, low-cost method to make a high-density memory device that includes deposited semiconductor material, and that is fabricated at low temperature, allowing the use of low-resistance conductors such as aluminum and copper.

In accordance with embodiments of the invention, a method for forming a memory cell including a polysilicon diode and aluminum or copper conductors is provided. An aluminum or copper conductor may be formed on a substrate. Above the conductor, a polysilicon diode may be formed using a hot wire chemical vapor deposition (“HWCVD”) technique. A memory element such as a dielectric rupture antifuse may be formed above the diode. A second aluminum or copper conductor is formed above the memory element. The methods described herein may be used to fabricate monolithic three dimensional memory arrays.

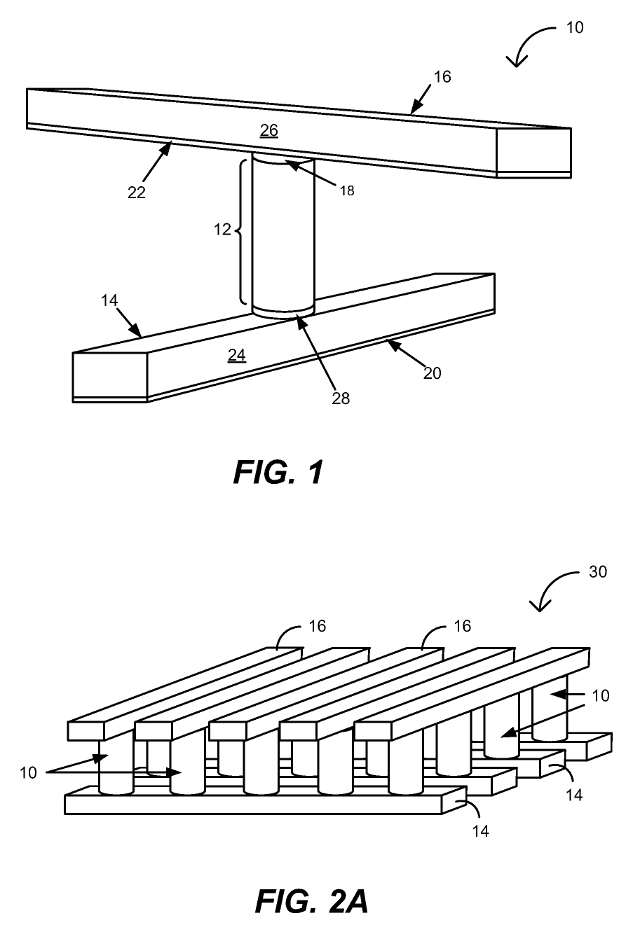

FIG. 1 shows a memory cell 50 taught in Herner et al., U.S. patent application Ser. No. 10/326,470 (the “'470 application”), since abandoned, and hereby incorporated by reference in its entirety for all purposes. The '470 application describes fabrication and use of a monolithic three dimensional memory array including such cells formed above a substrate, preferably of monocrystalline silicon. Related memory arrays, and their use and methods of manufacture, are taught in Herner et al., U.S. patent application Ser. No. 10/955,549, “Nonvolatile Memory Cell Without a Dielectric Antifuse Having High- and Low-Impedance States,” filed Sep. 29, 2004 (the “'549 application”), Herner et al., U.S. patent application Ser. No. 11/015,824, “Nonvolatile Memory Cell Comprising a Reduced Height Vertical Diode,” filed Dec. 17, 2004 (the “'824 application”), and Herner et al., U.S. patent application Ser. No. 10/954,577, “Junction Diode Comprising Varying Semiconductor Compositions,” filed Sep. 29, 2004 (the “'577 application”), each owned by the assignee of the present application and hereby incorporated by reference in its entirety for all purposes.

Referring to FIG. 1, in preferred embodiments of the '470 application a memory cell 10 includes a polysilicon diode 12 disposed between bottom conductor 14 and top conductor 16. Diode 12 may be separated from top conductor 16 by a dielectric rupture antifuse 18, typically a thin oxide layer. Cell 10 may be formed in an initial high-resistance state, and when a read voltage is applied between bottom conductor 14 and top conductor 16, little or no current flows between them. Upon application of a programming voltage, however, cell 10 may be permanently converted to a low-resistance state. In this low-resistance state, when the read voltage is applied between bottom conductor 14 and top conductor 16 a reliably detectable current flows. The initial high-resistance state may correspond to, for example, a data “0,” whereas the programmed low-resistance state corresponds to a data “1”.

The change from high-resistance to low-resistance state may result from at least two changes. The dielectric rupture antifuse 18 suffers dielectric breakdown and irreversibly ruptures, becoming conductive through a rupture path formed through antifuse 18. In addition, as described more fully in the '549 application, the semiconductor material of diode 12 is converted from a high-resistance state to a low-resistance state. Diode 12 is polycrystalline before programming. After a programming voltage is applied, polysilicon diode 12 is more conductive than prior to application of the programming voltage.

In preferred embodiments of the '470, '549, '824 and '577 applications, bottom conductor 14 and top conductor 16 include titanium nitride adhesion layers 20 and 22, and tungsten layers 24 and 26, respectively. A titanium nitride barrier layer 28 may separate the polysilicon of diode 12 from tungsten layer 24.

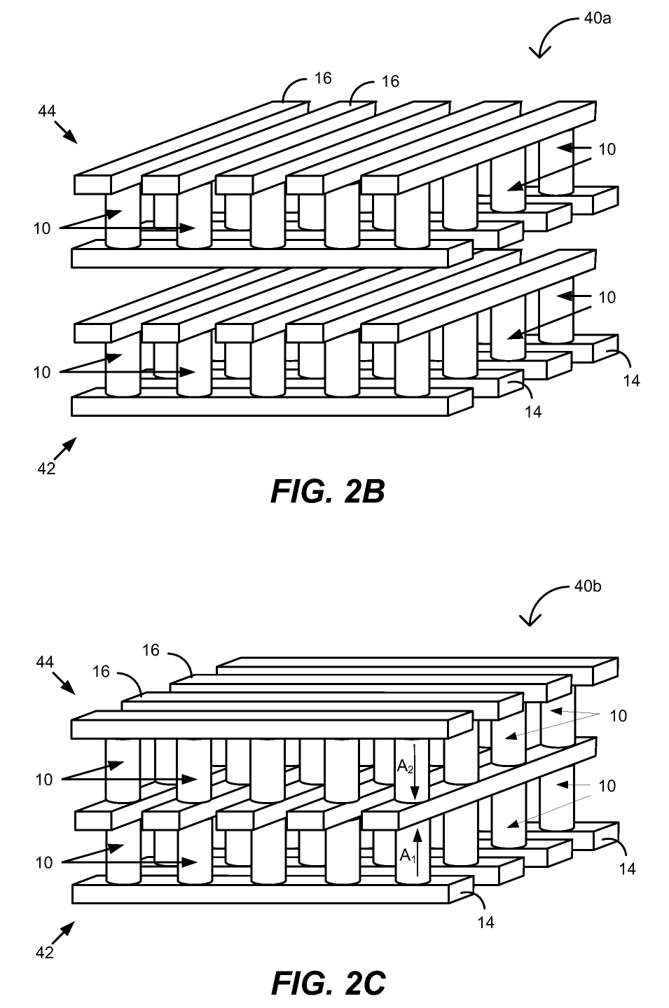

A plurality of such top and bottom conductors, with intervening diodes and antifuses, may be fabricated in an array, forming a first memory level. FIG. 2A is a simplified perspective view of a portion of a first memory level 30 formed from a plurality of memory cells 10, such as memory cells 10 of FIG. 1. For simplicity, diode 12 and antifuse 18 are not separately shown. Memory array 30 is a “cross-point” array including a plurality of bit lines (second conductors 16) and word lines (first conductors 14) to which multiple memory cells are coupled (as shown). Other memory array configurations may be used, as may multiple levels of memory.

For example, FIG. 2B is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2B for simplicity. Other memory array configurations may be used, as may additional levels of memory. In the embodiment of FIG. 2B, all diodes may “point” in the same direction, such as upward or downward depending on whether p-i-n diodes having a p-doped region on the bottom or top of the diodes are employed, simplifying diode fabrication.

For example, in some embodiments, the memory levels may be formed as described in U.S. Pat. No. 6,952,030, titled “High-Density Three-Dimensional Memory Cell” which is hereby incorporated by reference herein in its entirety for all purposes. For instance, the upper conductors of a first memory level may be used as the lower conductors of a second memory level that is positioned above the first memory level as shown in FIG. 2C. In such embodiments, the diodes on adjacent memory levels preferably point in opposite directions as described in U.S. patent application Ser. No. 11/692,151, filed Mar. 27, 2007 and titled “Large Array Of Upward Pointing P-I-N Diodes Having Large And Uniform Current” (the “'151 Application”), which is hereby incorporated by reference herein in its entirety for all purposes. For example, as shown in FIG. 2C, the diodes of first memory level 42 may be upward pointing diodes as indicated by arrow A1 (e.g., with p regions at the bottom of the diodes), whereas the diodes of second memory level 44 may be downward pointing diodes as indicated by arrow A2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

The memory cell 10 of FIG. 1 is highly effective for a wide range of dimensions. As the design is scaled to ever smaller dimensions, however, the cross-sectional areas of bottom conductor 14 and top conductor 16 decrease, and the resistance of the conductors increases. Compensating for decreasing width by increasing thickness quickly becomes impractical, as high-aspect ratio features are difficult to reliably pattern and etch and high-aspect ratio gaps are difficult to fill with dielectric. At very small feature size, tungsten conductors may be too highly resistive for successful device performance.

It would be desirable to use a low-resistivity material, such as aluminum or copper, to form the top and bottom conductors. As noted earlier, however, the crystallization of polysilicon diode 12 is conventionally performed at temperatures incompatible with the use of aluminum or copper.

In accordance with embodiments of the invention, a memory cell including a polysilicon diode and aluminum or copper conductors may be formed by using an HWCVD technique. HWCVD allows deposition of the polysilicon diode at low substrate temperatures, and may be compatible with aluminum or copper wiring pre-existing on the substrate.

Depositing silicon using HWCVD is well-known. For example, in at least one embodiment, a small metal diameter wire filament may be situated near a substrate and used as a hot element in the deposition process. The wire filament, which may be, for example, tungsten or tantalum, is heated, and a silicon-bearing gas such as SiH₄ is exposed to the hot filament. When the gas contacts the hot filament, the gas breaks down into its constituent parts, which are deposited onto the substrate.

Silicon deposited using a HWCVD method may achieve polycrystallinity at substrate temperatures below 400° C. In some examples, silicon deposited using a HWCVD method may achieve polycrystallinity at substrate temperatures below 250° C., for example. These temperature ranges are compatible with use of aluminum and copper conductors. It has been observed that the electrical performance of polysilicon deposited using HWCVD is similar to that achieved by polysilicon deposited using low pressure chemical vapor deposition (“CVD”) followed by a crystallizing anneal. The electrical performance of polysilicon deposited using HWCVD is discussed in Q. Wang et. al., “Low Temperature Thin-film Silicon Diodes for Consumer Electronics,” Mater. Res. Soc. Symp. Proc., vol. 862 (2005) (Materials Research Society), which is hereby incorporated by reference herein in its entirety for all purposes.

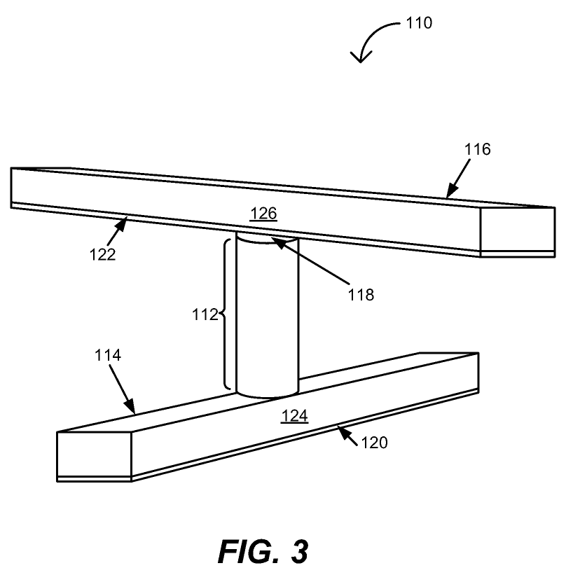

In accordance with embodiments of the invention, a memory cell including aluminum and/or copper conductors and a polysilicon diode formed using HWCVD is provided. FIG. 3 shows a memory cell 110 formed according to the present invention. In this embodiment bottom conductor 114 and top conductor 116 include aluminum layers 124 and 126, respectively; in alternate embodiments the conductors may include copper. Bottom conductor 114 and top conductor 116 may also include adhesion layers 120 and 122, respectively, formed of a suitable material such as titanium nitride. Diode 112 may be a polysilicon diode formed using an HWCVD technique. A memory element 118 may be arranged in series with diode 112 between the conductors. In the example of FIG. 3, memory element 118 may include a dielectric rupture antifuse, for example. Dielectric rupture antifuse 118 may be formed using any appropriate dielectric material, such as an oxide, nitride, or oxynitride. In other embodiments, memory element 118 may include other types of memory devices.

In accordance with embodiments of the invention, a memory cell including aluminum and/or copper conductors and a polysilicon diode may be formed using a HWCVD technique. As mentioned above, use of HWCVD may allow the crystallization temperature of the diode to be reduced below 400° C., preferably below about 250° C.

Two detailed exemplary fabrication methods in accordance with this invention are described herein, each of a different monolithic three dimensional memory array formed according to the present invention. The first exemplary method will describe use of aluminum conductors, whereas the second exemplary method will describe use of copper conductors. Persons of ordinary skill in the art will understand that copper conductors may be used with the first exemplary method, and aluminum conductors may be used with the second exemplary method. For clarity, many details, including steps, materials, and process conditions, will be included. It will be understood that these examples are non-limiting, and that these details may be modified, omitted, or augmented, whereas the results fall within the scope of the invention. Specifically, teachings of the '470, '549, '824, '577 and other incorporated applications and patents may be relevant to formation of a memory according to the present invention. For simplicity, not all of the details of the incorporated applications and patents will be included, but it will be understood that no teaching of these applications or patents is intended to be excluded.

### EXAMPLE

### Aluminum Conductors

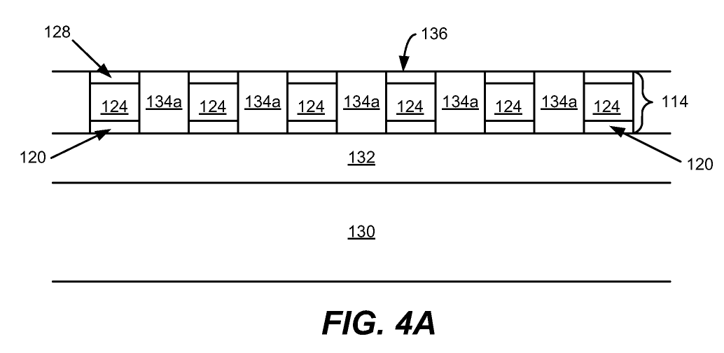

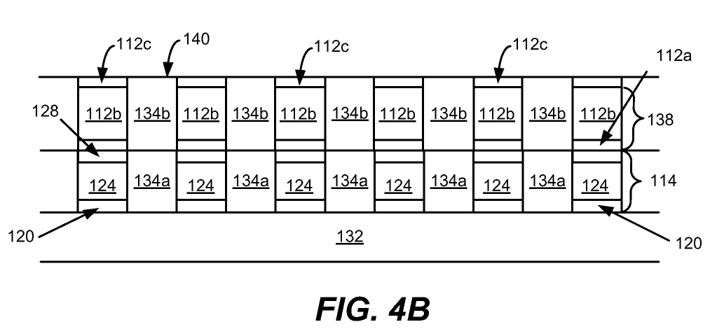

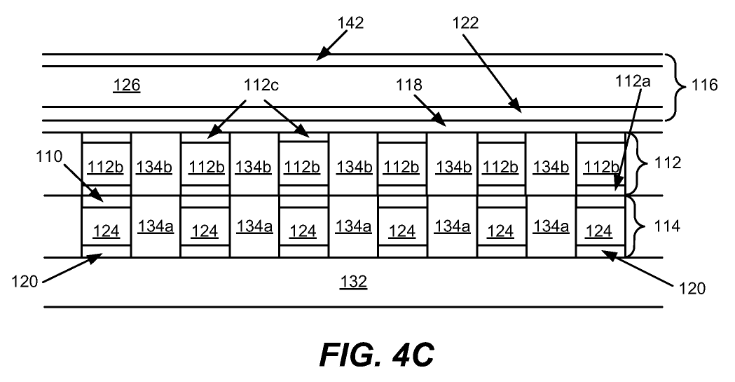

Referring now to FIG. 4A, an exemplary method in accordance with this invention for forming a memory device including aluminum conductors is now described. Formation of the memory begins with a substrate 130. This substrate 130 may be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 132 may be formed over substrate 130. Insulating layer 132 may include silicon oxide, silicon nitride, high-dielectric film, Si—C—O—H film, or any other suitable insulating material.

The first conductors 114 may be formed over substrate 130 and insulating layer 132. An adhesion layer 120 may be included between insulating layer 132 and conducting layer 124 to help conducting layer 124 adhere. A preferred material for adhesion layer 120 is titanium nitride, although other materials may be used, or this layer may be omitted. Adhesion layer 120 may be deposited by any conventional method, for example by sputtering.

The thickness of adhesion layer 120 may range from about 20 to about 500 angstroms, and is preferably between about 100 and about 400 angstroms, most preferably about 200 angstroms. Note that in this discussion, “thickness” will denote vertical thickness, measured in a direction perpendicular to substrate 130.

Conducting layer 124 may be formed over adhesion layer 120. In the present embodiment, conducting layer 124 may include aluminum or an aluminum alloy, though in less preferred embodiments, other conducting materials known in the art, such as doped semiconductor, or metal silicides may be used. The thickness of conducting layer 124 may depend, in part, on the desired sheet resistance and therefore can be any thickness that provides the desired sheet resistance. In one embodiment, the thickness of conducting layer 124 may range from about 500 to about 3000 angstroms, preferably about 1000 to about 2000 angstroms, most preferably about 1200 angstroms.

A barrier layer 128, preferably of titanium nitride, may be deposited on conducting layer 124. Barrier layer 128 may be about the same thickness as adhesion layer 120. An antireflective coating may be used. Barrier layer 128 may serve as a barrier between aluminum layer 124 and the diodes yet to be formed.

Once all the layers that will form the conductor rails have been deposited, the layers may be patterned and etched using any suitable masking and etching process to form substantially parallel, substantially coplanar conductors 114, shown in FIG. 4A in cross-section. In one embodiment, photoresist is deposited, patterned by photolithography and the layers etched, and then the photoresist removed, using standard process techniques such as “ashing” in an oxygen-containing plasma, and stripped of remaining polymers formed during etch in a conventional liquid solvent such as those formulated by EKC Technology, Inc., Hayward, Calif.

In a repeating pattern, pitch is the distance between a feature and the next recurrence of the same feature. In a plurality of substantially parallel lines like conductors 114, for example, the pitch of conductors 114 is the distance from the center of one line to the center of the next line. Conductors 114 may be formed at any desired pitch, but the pitch of conductors 114 is preferably no more than about 180 nm, more preferably no more than about 150 nm, still more preferably no more than about 120 nm, and most preferably no more than about 90 nm. The pitch of conductors 114 may be less than 90 nm.

Next a dielectric material 134a may be deposited over and between conductor rails 114. Dielectric material 134a may be any known electrically insulating material, such as silicon oxide, silicon nitride, or silicon oxynitride. In a preferred embodiment, silicon dioxide may be used as dielectric material 134a. The silicon oxide may be deposited using any known process, such as CVD, or, for example, HDPCVD. Dielectric layer 134a may have a thickness of about 2000-7000 angstroms.

Finally, dielectric material 134a on top of conductor rails 114 may be removed, exposing the tops of conductor rails 114 separated by dielectric material 134a, and leaving a substantially planar surface 136. The resulting structure is shown in FIG. 4A. This removal of dielectric overfill to form planar surface 136 may be performed by any process known in the art, such as etchback or chemical-mechanical planarization (“CMP”). For example, the etchback techniques described in Raghuram et al., U.S. patent application Ser. No. 10/883,417, “Nonselective Unpatterned Etchback to Expose Buried Patterned Features,” filed Jun. 30, 2004 and hereby incorporated by reference in its entirety for all purposes, may advantageously be used.

If this planarization step is performed by CMP, some thickness of barrier layer 128, for example, about 600 angstroms, may be lost. In this case an extra sacrificial thickness of titanium nitride may be provided, such that preferably at least about 200 angstroms of titanium nitride remains after CMP.

Turning to FIG. 4B, vertical pillars may be formed above conductor rails 114. (To save space substrate 130 is omitted in FIG. 4B and subsequent figures; its presence will be assumed in this and subsequent figures). Accordingly, semiconductor material that will be patterned into pillars may be deposited. The semiconductor material may include a silicon-based material such as silicon, silicon-germanium, silicon-germanium-carbon, or a combination. In preferred embodiments, silicon and doped silicon may be used. The present example will describe the use of pure silicon. The term “pure silicon” does not exclude the presence of conductivity-enhancing dopants or contaminants normally found in a typical production environment.

In an exemplary embodiment, the semiconductor pillar comprises a junction diode. The term junction diode is used herein to refer to a semiconductor device with the property of non-ohmic conduction, having two terminal electrodes, and made of semiconducting material which is p-type at one electrode and n-type at the other. Examples include p-n diodes and n-p diodes, which have p-type semiconductor material and n-type semiconductor material in contact, such as Zener diodes, and p i n diodes, in which intrinsic (undoped) semiconductor material is interposed between p-type semiconductor material and n-type semiconductor material.

In at least some embodiments, the junction diode may comprise a bottom heavily doped region of a first conductivity type and a top heavily doped region of a second conductivity type opposite the first. The middle region, between the top and bottom regions, may be an intrinsic or lightly doped region of either the first or second conductivity type. Such a diode can be described as a p-i-n diode.

Referring to FIG. 4B, bottom heavily doped region 112a may be deposited using HWCVD at temperatures between about 150° C. and about 250° C., more generally between about 100° C. and about 400° C. Silicon deposited by HWCVD may achieve polycrystallinity at these temperatures. In this example, bottom heavily doped region 112a may be heavily doped n-type silicon. In a most preferred embodiment, bottom heavily doped region 112a is deposited and doped with an n-type dopant such as phosphorus by any conventional method, preferably by in situ doping. This layer may have a thickness between about 200 angstroms and about 800 angstroms, more generally between about 50 and about 1000 angstroms. In some alternative embodiments, bottom heavily doped region 112a may be deposited using plasma enhanced chemical vapor deposition (“PECVD”) at temperatures less than about 400° C.

Next, the silicon that will form the remainder of the diode may be deposited. Silicon may be deposited using HWCVD at temperatures between about 150° C. and about 250° C., more generally between about 100° C. and about 400° C. In some alternative embodiments, silicon may be deposited using PECVD at temperatures between about 100° C. and about 400° C.

Silicon layer 112b may have a thickness of about 1500-2500 angstroms, more generally between about 800-4000 angstroms. In at least one embodiment, silicon layer 112b has a thickness between about 1800 and about 2200 angstroms. If desired, silicon layer 112b may be lightly doped. Heavily doped top region 112c, which may be formed on top of silicon layer 112b, may be doped with a p-type dopant such as boron by in situ doping. Silicon layer 112c may have a thickness of about 200-2000 angstroms, more generally between about 50-1500 angstroms. In some embodiments a subsequent planarization step may be employed to remove some silicon, so an extra thickness may be deposited.

If the planarization step is performed using a conventional CMP method, about 800 angstroms of thickness may be lost (this is an average; the amount varies across the wafer. Depending on the slurry and methods used during CMP, the silicon loss may be more or less.). If the planarization step is performed by an etchback method, only about 400 angstroms of silicon or less may be removed.

The silicon just deposited may be patterned and etched to form pillars 138. Pillars 138 may have about the same pitch and about the same width as conductors 114 below, such that each pillar 138 is formed on top of a conductor 114. Some misalignment may be tolerated.

Pillars 138 may be formed using any suitable masking and etching process. For example, photoresist may be deposited, patterned using standard photolithography techniques, layers 112c, 112b and 112a may be etched, and then the photoresist may be removed. Alternatively, a hard mask of some other material, for example silicon dioxide, may be formed on top of the semiconductor layer stack, with bottom antireflective coating (“BARC”) on top, then patterned and etched. Similarly, dielectric antireflective coating (“DARC”) may be used as a hard mask.

The photolithography techniques described in Chen, U.S. patent application Ser. No. 10/728436, “Photomask Features with Interior Nonprinting Window Using Alternating Phase Shifting,” filed Dec. 5, 2003; or Chen, U.S. patent application Ser. No. 10/815312, Photomask Features with Chromeless Nonprinting Phase Shifting Window,” filed Apr. 1, 2004, both owned by the assignee of the present invention and hereby incorporated by reference in their entireties for all purposes, may advantageously be used to perform any photolithography step used in formation of a memory array according to the present invention.

Dielectric material 134b may be deposited over and between pillars 138, filling the gaps between them. Dielectric material 134b may include any known electrically insulating material, such as silicon oxide, silicon nitride, or silicon oxynitride. In a preferred embodiment, silicon dioxide may be used as the insulating material. The silicon dioxide may be deposited using any known process, such as CVD or HDPCVD. Dielectric material 134b may have a thickness of about 2000-7000 angstroms.

Next, dielectric material 134b on top of pillars 138 may be removed, exposing the tops of pillars 138 separated by dielectric material 134b, and leaving a substantially planar surface 140. This removal of dielectric overfill and planarization may be performed by any process known in the art, such as CMP or etchback. For example, the etchback techniques described in Raghuram et al. may be used. The resulting structure is shown in FIG. 4B.

Diode 112 has a bottom n-type region 112a and a top p-type region 112c. If preferred, the conductivity types could be reversed. If desired, p-i-n diodes having an n-region on the bottom may be used in one memory level while p-i-n diodes having a p-type region on the bottom may be used in another memory level.

A memory element may be formed above diodes 112. In this example, a memory element 118 may be formed using a dielectric rupture antifuse material. Dielectric rupture antifuse 118 may formed by any low-temperature deposition of an appropriate dielectric material. For example, a layer of Al₂O₃ may be deposited at temperatures between about 100° C. and about 150° C., more generally between about 50° C. and about 400° C.

Alternatively the antifuse may be liquid phase deposited silicon dioxide, also a low-temperature process. Suitable methods are described by Nishiguchi et al. in “High quality SiO₂ film formation by highly concentrated ozone gas at below 600 C,” Applied Physics Letters 81, pp. 2190-2192 (2002), and by Hsu et al. in “Growth and electrical characteristics of liquid-phase deposited SiO2 on Ge,” Electrochemical and Solid State Letters 6, pp. F9-F11 (2003), each of which are hereby incorporated by reference in its entirety for all purposes. Other alternatives include a nitride or oxynitride formed by a low-temperature method. Dielectric rupture antifuse 118 may preferably be between about 20 and about 80 angstroms thick, preferably about 50 angstroms thick. In some embodiments, dielectric rupture antifuse 118 may be omitted.

In other embodiments, memory element 118 may include other types of memory devices. For example, memory element 118 may include a reversible resistance switching element. Various types of reversible resistance switching elements, and methods of forming the same, are described in U.S. patent application Ser. No. 11/692,144, “Method To Form A Memory Cell Comprising A Carbon Nanotube Fabric Element And A Steering Element,” filed on Mar. 27, 2007, and U.S. patent application Ser. No. 11/968,156, “Memory Cell That Employs A Selectively Fabricated Carbon Nano-Tube Reversible Resistance-Switching Element Formed Over A Bottom Conductor And Methods Of Forming The Same,” filed on Dec. 31, 2007, each of which is assigned to the assignee of the present invention and is hereby incorporated by reference in its entirety for all purposes.

Next a conductive material or stack may be deposited to form the top conductors 116. In a preferred embodiment, titanium nitride barrier layer 122 having a thickness between about 50-1000 angstroms may be deposited, followed by aluminum layer 126 having a thickness between about 1000-10000 angstroms, and top titanium nitride barrier layer 142 having a thickness between about 50-3000 angstroms. Top conductors 116 may be patterned and etched as described earlier. Overlying second conductors 116 preferably extend in a different direction from first conductors 114, preferably substantially perpendicular to them. The resulting structure, shown in FIG. 4C, is a bottom or first story of memory cells. Ideally each top conductor 116 is formed directly aligned with a row of diodes 112. Some misalignment may be tolerated. Each memory level comprises bottom conductors 114, diodes 112, and top conductors 116. Bottom conductors 114 may be substantially parallel and extend in a first direction, and top conductors 116 may be substantially parallel and extend in a second direction different from the first direction.

Note that in this memory level, for each memory cell, bottom conductor 114, diode 112, and top conductor 116 may be each patterned in a separate patterning step.

Additional memory levels may be formed above this first memory level. In some embodiments, conductors may be shared between memory levels; i.e., top conductor 116 may serve as the bottom conductor of the next memory level. In other embodiments, an interlevel dielectric (not shown) may be formed above the first memory level of FIG. 4C, its surface planarized, and construction of a second memory level may begin on this planarized interlevel dielectric, with no shared conductors.

Vertical interconnects between memory levels and between circuitry in the substrate may be formed of aluminum by any conventional method.

Photomasks may be used during photolithography to pattern each layer. Certain layers may be repeated in each memory level, and the photomasks used to form them may be reused. For example, a photomask defining diodes 112 of FIG. 4C may be reused for each memory level. Each photomask includes reference marks used to properly align it. When a photomask is reused, reference marks formed in a second or subsequent use may interfere with the same reference marks formed during a prior use of the same photomask. Chen et al., U.S. patent application Ser. No. 11/097,496, “Masking of Repeated Overlay and Alignment Marks to Allow Reuse of Photomasks in a Vertical Structure,” filed Mar. 31, 2005, and hereby incorporated by reference in its entirety for all purposes, describes a method to avoid such interference during the formation of a monolithic three dimensional memory array like that of the present invention.

### EXAMPLE

### Copper Conductors

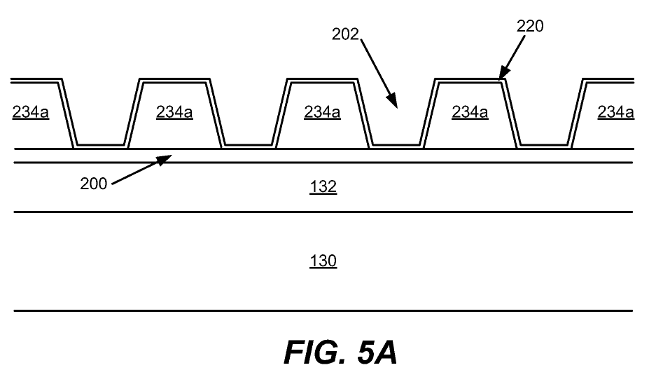

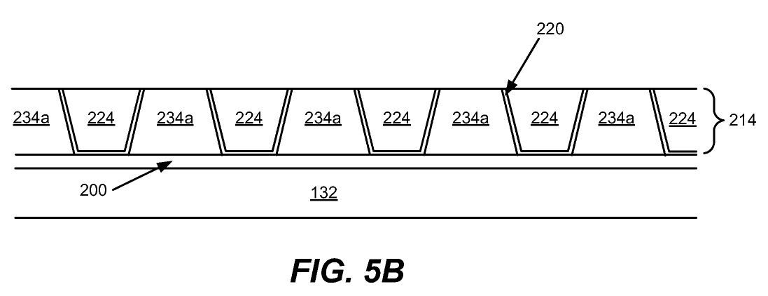

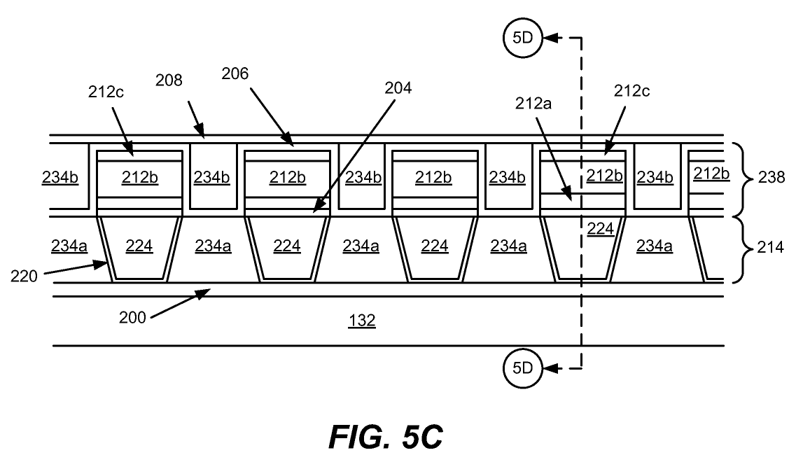

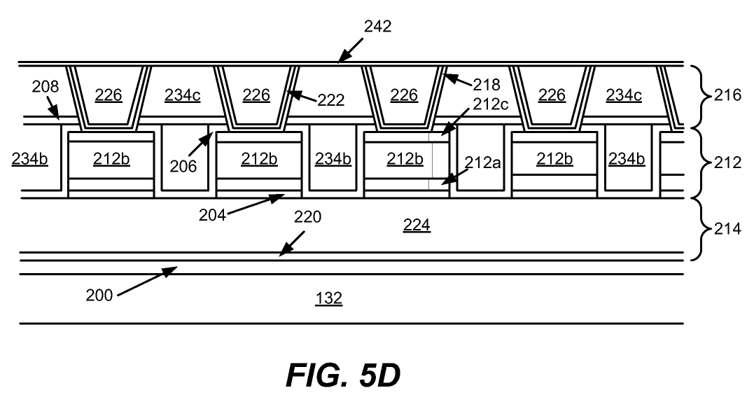

Referring now to FIG. 5A, an alternative exemplary method in accordance with this invention for forming a memory device including copper conductors is now described. In this embodiment, fabrication begins as before over substrate 130 and insulating layer 132, which may be formed as described in the previous embodiment.

In an exemplary embodiment, a layer 200 of, for example, silicon nitride may be deposited on insulating layer 132. Layer 200 may have a thickness between about 400-1500 angstroms, more generally between about 200-3000 angstroms. This layer may serve as an etch stop during a damascene etch to come.

Next a layer 234a of a dielectric, for example TEOS, may be deposited. Its thickness may be between about 1000 and about 6000 angstroms, preferably about 4000 angstroms. A conventional damascene etch may be performed to etch substantially parallel trenches 202. The etch stops on silicon nitride layer 200. A barrier layer 220 of, for example, tantalum nitride, tantalum, tungsten, tungsten nitride, titanium nitride, or any other appropriate material may be conformally deposited covering dielectric layer 234a and lining trenches 202.

As shown in FIG. 5B, copper layer 224 may be deposited on barrier layer 220, filling trenches 202. Copper layer 224 is preferably substantially pure copper, though an alloy of copper may be used if desired. Copper layer 224 may have a thickness between about 1500-5000 angstroms, more generally between about 1000-10000 angstroms. A planarization step, for example by CMP, removes overfill of copper 224, co-exposing copper layer 224 and dielectric layer 234a, as well as barrier layer 220, at a substantially planar surface. In this manner, bottom conductors 214 have been formed. The pitch of bottom conductors 214 may be as described in the previous embodiment.

Turning to FIG. 5C, a conductive barrier layer 204 may be deposited on the planar surface. This barrier layer 204 is preferably tantalum nitride or tantalum, though other suitable materials may be used. Barrier layer 204 may have a thickness between about 100-500 angstroms, more generally between about 50-2000 angstroms.

Next a silicon or silicon alloy layerstack that may be etched to form the diodes may be deposited as in the previous embodiment, including heavily doped n-type silicon layer 212a, undoped silicon layer 212b and heavily doped p-type layer 212c. Silicon or any of the previously-mentioned silicon alloys may be used. Silicon may be deposited using HWCVD at temperatures between about 150° C. and about 250° C., more generally between about 100° C. and about 400° C. Silicon deposited using HWCVD may achieve polycrystallinity at these temperatures, which are compatible with use of aluminum or copper conductors. In some alternative embodiments, silicon may be deposited using PECVD at temperatures between about 100° C. and about 400° C.

Silicon layer 212a may have a thickness between about 200 angstroms and about 800 angstroms, more generally between about 50 angstroms and about 1000 angstroms. Silicon layer 212b may have a thickness between about 1500-2500 angstroms, more generally between about 800-4000 angstroms. Silicon layer 212c may have a thickness between about 200-2000 angstroms, more generally between about 50-1500 angstroms.

The silicon just deposited may be patterned and etched to form pillars 238. Tantalum nitride barrier layer 204 is etched as well, leaving copper layer 224 exposed between the pillars. Pillars 238 may have about the same pitch and about the same width as conductors 214 below, such that each pillar 238 is formed on top of a conductor 214. Some misalignment may be tolerated.

In general, copper must be encapsulated to avoid its diffusion into other materials. A thin layer 206 of an appropriate dielectric barrier material, for example between about 100-2000 angstroms of silicon carbide, silicon nitride, a Si—C—O—H film, or some other high-K dielectric may be deposited next, covering dielectric 234a and encapsulating copper 224 in conductors 214. Silicon carbide barrier dielectric 206 may also cover the tops of pillars 238, and, depending on the step coverage of the material, may cover the sidewalls of pillars 238 as well. An oxide 234b or other appropriate gap fill material may be deposited, for example by HDPCVD, filling gaps between the pillars 238. Dielectric layer 234b may fill past the top of the pillars 238.

Next dielectric material 234b on top of the pillars 238 may be removed, exposing the tops of silicon carbide barrier dielectric 206 on top of pillars 238 separated by dielectric material 234b, and leaving a substantially planar surface. This removal of dielectric overfill and planarization may be performed by any process known in the art, such as CMP or etchback. For example, the etchback techniques described in Raghuram et al. may be used. Next a silicon nitride etch stop layer 208 may be deposited on the planar surface. The resulting structure is shown in FIG. 5C.

Referring now to FIG. 5D, the exemplary processing steps continue. Note that FIG. 5D illustrates a cross-sectional view that is perpendicular to the views of FIGS. 5A-5C. Dielectric material 234c may be deposited on silicon nitride etch stop layer 208; its thickness is preferably comparable to that of dielectric 234c in which bottom conductors 214 were formed. Next, trenches may be etched in dielectric 234c. The etch may stop at silicon nitride etch stop layer 208. A low-rate etch may remove first silicon nitride layer 208, then silicon carbide layer 206, exposing the tops of pillars 212.

Next, a dielectric rupture antifuse 218 may be formed, preferably by atomic layer deposition of Al₂O₃, conformally filling the trenches. Alternative methods of forming dielectric rupture antifuse 218, as described in the previous embodiment, may be used instead. Dielectric rupture layer 218 is preferably between about 15 and about 80 angstroms thick, preferably about 50 angstroms thick. In some embodiments, dielectric rupture antifuse 218 may be omitted.

Top conductors 216 may be formed in the same manner as bottom conductors 214. Barrier layer 222, preferably of tantalum nitride, may be formed to line the trenches, and copper layer 226 may be formed to fill the trenches. A planarization step, for example by CMP, may remove overfill of copper, forming top conductors 216 and creating a substantially planar surface. If an interlevel dielectric is to be formed between this memory level and the next, a dielectric barrier layer 242, for example of silicon carbide, may be deposited on this substantially planar surface to encapsulate copper layer 226.

If instead the next memory level is to share top conductors 216, i.e., if top conductors 216 are to serve as the bottom conductors of the next memory level, then a conductive nitride barrier layer such as tantalum nitride may be deposited on the substantially planar surface instead (not shown.) The silicon stack to form the next set of pillars may be deposited next, and fabrication continues as described for pillars 212, with the conductive barrier layer etched with the pillars, deposition of a conformal high-K barrier dielectric over the pillars and the copper, etc.

Vertical interconnects between memory levels and between circuitry in the substrate may be formed of copper in a conventional dual damascene process.

The memory cell of the present invention has been described herein in the context of a monolithic three dimensional memory array, but may be advantageous in any other context requiring low fabrication temperature, for example with certain low-temperature substrates.

Detailed methods of fabrication have been described herein, but any other methods that form the same structures may be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

1. A method of forming a monolithic three-dimensional memory array, the method comprising:
forming a first memory level that includes a plurality of memory cells, each memory cell comprising a plurality of conductors comprising aluminum or copper; and
forming a silicon diode in each memory cell using a hot wire chemical vapor deposition technique, wherein the silicon diode is formed at temperatures compatible with the conductors.

2. (canceled)

3. The method of claim 1, wherein forming the silicon diode comprises forming the silicon diode using a hot wire chemical vapor deposition technique at processing temperatures below about 400° C.

4. The method of claim 3, wherein forming the silicon diode comprises forming the silicon diode using a hot wire chemical vapor deposition technique at processing temperatures below about 250° C.

5. (canceled)

6. The method of claim 1, wherein forming the silicon diode comprises forming a polycrystalline silicon diode.

7. The method of claim 1, wherein forming the first memory layer further comprises forming a memory element coupled to the silicon diode.

8. The method of claim 7, wherein the memory element comprises a dielectric rupture antifuse.

9. The method of claim 7, wherein the memory element comprises a reversible resistance switching element.

10. A monolithic three-dimensional memory array formed using the method of claim 1.

11. A monolithic three-dimensional memory array comprising:
a first conductor comprising copper or aluminum;
a polycrystalline silicon element coupled to the first conductor; and
a second conductor coupled to the polycrystalline silicon element, the second conductor comprising copper or aluminum.

12. The memory array of claim 11, wherein the polycrystalline silicon element comprises a diode.

13. The memory array of claim 12, wherein the polycrystalline silicon element comprises a p-i-n diode.

14. The memory array of claim 11, further comprising a memory element coupled to the polycrystalline silicon element.

15. The memory array of claim 14, wherein the memory element comprises a dielectric rupture antifuse.

16. The memory array of claim 14, wherein the memory element comprises a reversible resistance switching element.

17. A method of forming a memory cell, comprising:
forming a conductor of copper or aluminum; and
using a hot wire chemical vapor deposition technique to form a polycrystalline silicon element coupled to the conductor.

18. The method of claim 17, wherein the polycrystalline silicon element comprises a polysilicon diode.

19. The method of claim 18, wherein the polycrystalline silicon element comprises a polysilicon p-i-n diode.

20. The method of claim 17, further comprising forming a memory element coupled to the polycrystalline silicon element.

21. The method of claim 20, wherein the memory element comprises a dielectric rupture antifuse.

22. The method of claim 20, wherein the memory element comprises a reversible resistance switching element.

23. The method of claim 17, comprising using a hot wire chemical vapor deposition method at processing temperatures below about 400° C.

24. The method of claim 23, comprising using a hot wire chemical vapor deposition method at processing temperatures below about 250° C.

25. A memory cell formed using the method of claim 17.
